(19) United States
(12) Patent Application Publication
(10) Pub. No.: US 2015/0111374 A1
(43) Pub. Date: Apr. 23, 2015

(54) SURFACE TREATMENT IN A DEP-ETCH-DEP PROCESS

(71) Applicant: International Business Machines Corporation, Armonk, NY (US)

(72) Inventors: Ruqiang Bao, Wappingers Falls, NY (US); Domingo A. Ferrer, Fishkill, NY (US); Filippos Papadatos, Wappingers Falls, NY (US); Daniel P. Stambaugh, Rhinebeck, NY (US)

(73) Assignee: International Business Machines Corporation, Armonk, NY (US)

(21) Appl. No.: 14/057,529

(22) Filed: Oct. 18, 2013

(51) Int. Cl. H01L 21/3065; H01L 21/768; H01L 29/66

(52) U.S. Cl. CPC H01L 21/30655; H01L 29/66545; H01L 21/76879
USPC 438/586; 438/637; 438/669

(57) ABSTRACT

Embodiments of present invention provide a method of forming semiconductor devices. The method includes creating an opening in a semiconductor structure; depositing a first layer of metal inside the opening with the first layer of metal partially filling up the opening; modifying a top surface of the first layer of metal in an etching process; passivating the modified top surface of the first layer of metal to form a passivation layer; and depositing a second layer of metal directly on top of the passivation layer.

### FIELD OF THE INVENTION

The present invention relates generally to the field of semiconductor device manufacturing and in particular relates to a method of reducing growth delay in a dep-etch-dep metal fill process.

### BACKGROUND

Continuing scaling in manufacturing of complementary-metal-oxide-semiconductor (CMOS) transistors such as transistors with replacement-metal-gate (RMG), and of semiconductor devices in general including interconnects, has frequently led to situations where trenches and via holes of high aspect ratio need to be filled up with conductive material and/or metal element to form, for example, interconnects and/or contacts. Conventional approaches of filling, for example, a deep trench have been found ineffective, often resulting in pinches at the opening of the trench which ultimately cause voids being formed inside the trench.

Recently, an “extreme fill” process has been developed to mitigate the above ineffectiveness and/or problem relating to metal fill in trenches and via holes in connection with applications for small features, particularly like those frequently found in logic circuit and eDRAM. Particularly, this extreme fill process is a deposition-etching-deposition (“dep-etch-dep” in short) process during which metal is first deposited partially in, for example, a trench which is then followed by an etching process designed to re-open up and smooth out surface of deposited metal. A second metal deposition is subsequently performed that typically finishes or completes the process of metal fill in the trench. In situations where thick metal fill is needed or desirable, the dep-etch-dep process may be repeated until the entire trench is filled.

However, the above current dep-etch-dep process has its drawbacks. For example, in situation where tungsten (W) is deposited, the process is typically accompanied by a delay in the growth of W during the second deposition step, and the delay could amount up to 170 seconds for example at a deposition temperature of 300 degree C. Additionally, the W deposited during the second deposition step in general has poor uniformity. For example, W deposition rate at the edge of a semiconductor wafer may be much faster than that at the center of the wafer which as a result causes performance variation among devices depending upon where the devices are manufactured in the wafer. In some instances observed so far, variations of deposited W thickness were measured to be as high as 64% in difference across a single wafer. The above drawbacks, both in the delay of W deposition rate and in the uniformity of thickness, significantly impact not only throughput of any manufacturing tool that adopts this dep-etch-dep process, but also consistency of electrical properties of devices manufactured by such dep-etch-dep process.

### SUMMARY OF EMBODIMENTS OF THE INVENTION

Embodiments of present invention provide a method of forming semiconductor devices. The method includes creating a structural opening in a process of manufacturing a semiconductor device; depositing a first layer of metal inside the structural opening, the first layer of metal resulting in a narrowed opening, inside the structural opening, surrounded by the first layer of metal; etching the first layer of metal to create an etching-modified surface of the first layer of metal; passivating the etching-modified surface of the first layer of metal; and depositing a second layer of metal inside the structural opening after the passivating, the second layer of metal substantially filling up the structural opening. In one embodiment, both the first layer of metal and the second layer of metal are tungsten (W) metal.

According to one embodiment, passivating the etching-modified surface of the first layer of metal includes passivating nitride (N) element that are caused to remain at the etching-modified surface by etching the first layer of metal.

For example, in one embodiment, passivating the etching-modified surface of the first layer of metal includes exposing the etching-modified surface to a mixture of gases of B₂H₆ and WF₆ or a mixture of gases of silane and WF₆, for a duration of 10 seconds or less, in a chemical vapor deposition (CVD) process. In another embodiment, passivating the etching-modified surface of the first layer of metal includes exposing the etching-modified surface to alternate gases of B₂H₆ and WF₆ or alternate gases of silane and WF₆ in an atomic-layer-deposition (ALD) process.

According to another embodiment, etching the first layer of metal includes subjecting the first layer of metal to a plasma environment supported by a NF₃ gas to widen at least an upper portion of the narrowed opening formed by the first layer of metal.

In one embodiment, the semiconductor device is a transistor with a replacement-metal-gate (RMG) and creating the structural opening includes removing dummy material of a dummy gate where the RMG is to be formed thereby resulting in the structural opening.

In another embodiment, the semiconductor device is an interconnect structure and creating the structural opening includes creating a via hole or a trench in one or more dielectric layers inside the interconnect structure.

In yet another embodiment, passivating the etching-modified surface of the first layer of metal results in a passivation layer at the etching-modified surface, and wherein the second layer of metal is deposited directly on top of the passivation layer.

### BRIEF DESCRIPTION OF THE DRAWINGS

The present invention will be understood and appreciated more fully from the following detailed description of preferred embodiments, taken in conjunction with the accompanying drawings of which:

FIG. 1 is a demonstrative illustration of a current dep-etch-dep process for performing metal fill as is known in the art;

FIG. 2 is a sample chart of experimental data illustrating delay in metal fill in the conventional dep-etch-dep process;

FIGS. 3A-3D are a demonstrative illustrations of an improved dep-etch-dep process for performing metal fill according to one embodiment of present invention;

FIG. 4 is a simplified flow chart illustration of an improved dep-etch-dep process for performing metal fill according to another embodiment of present invention;

FIG. 5 is a sample data illustration demonstrating tungsten deposition during surface treatment according to one embodiment of present invention;

FIG. 6 is a sample data illustration demonstrating improvement in growth rate in an improved dep-etch-dep process according to another embodiment of present invention; and

FIG. 7 is a sample data illustration demonstrating improvement in growth rate in an improved dep-etch-dep process according to yet another embodiment of present invention.

It will be appreciated that for purpose of simplicity and clarity of illustration, elements in the drawings have not necessarily been drawn to scale. For example, dimensions of some of the elements may be exaggerated relative to those of other elements for clarity purpose.

### DETAILED DESCRIPTION OF EMBODIMENTS OF THE INVENTION

In the following detailed description, numerous specific details are set forth in order to provide a thorough understanding of various embodiments of the invention. However, it is to be understood that embodiments of the invention may be practiced without these specific details.

In the interest of not obscuring presentation of essences and/or embodiments of the invention, in the following detailed description, some processing steps and/or operations that are known in the art may have been combined together for presentation and/or for illustration purpose and in some instances may have not been described in detail. In other instances, some processing steps and/or operations that are known in the art may not be described at all. In addition, some well-known device processing techniques may have not been described in detail and, in some instances, may be referred to other published articles, patents, and/or published patent applications for reference in order not to obscure description of essence and/or embodiments of the invention. It is to be understood that the following descriptions may have rather focused on distinctive features and/or elements of various embodiments of the invention.

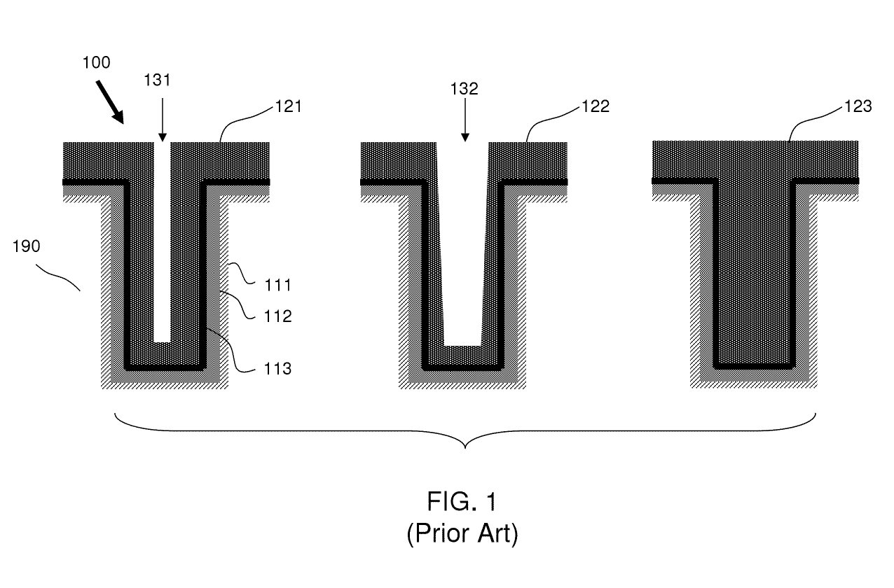

FIG. 1 is a demonstrative illustration of a current dep-etch-dep process for performing metal fill as is known in the art. In current semiconductor device manufacturing process, it is often needed to metal fill trenches and/or via holes of high aspect ratio in order to form interconnects or contacts. In addition, metal fill may be used in a replacement-metal-gate process as well in forming metal gate. In order to avoid creating void (which causes increase in contact resistance) inside the formed metal structure such as metal contact or metal gate, the conventional metal fill process was recently modified to become a dep-etch-dep process as being demonstratively illustrated in FIG. 1, using forming a metal structure inside a trench as an example.

More specifically, in the current dep-etch-dep process of forming trench metal structure inside a semiconductor substrate 190, a trench 100 may first be created inside substrate 190. Subsequently, an insulator layer 111 and a Ti/TiN barrier layer 112 may be deposited to line trench 100. Next, before performing metal fill inside trench 100, a seed layer 113 may be deposited on top of barrier layer 112 inside trench 100 in order to promote subsequent metal fill/deposition process. The current dep-etch-dep process then performs a first deposition of metal layer 121 inside trench 100. This first deposition of metal may partially fill and thus cause narrowing of trench 100, particularly narrowing (not shown in FIG. 1) around the upper portion of the formed metal layer 121 to have a small opening 131. The current dep-etch-dep process then applies an etching step to cause opening 131 to be widened, particularly at the top portion of trench 100, to become a new opening 132 by etching deposited metal layer 121 to have the shape of a modified metal layer 122. Following the widening of opening 131 by the etching process, a second metal deposition process may be applied such that trench 100 may be completely filled up to have a final metal layer 123.

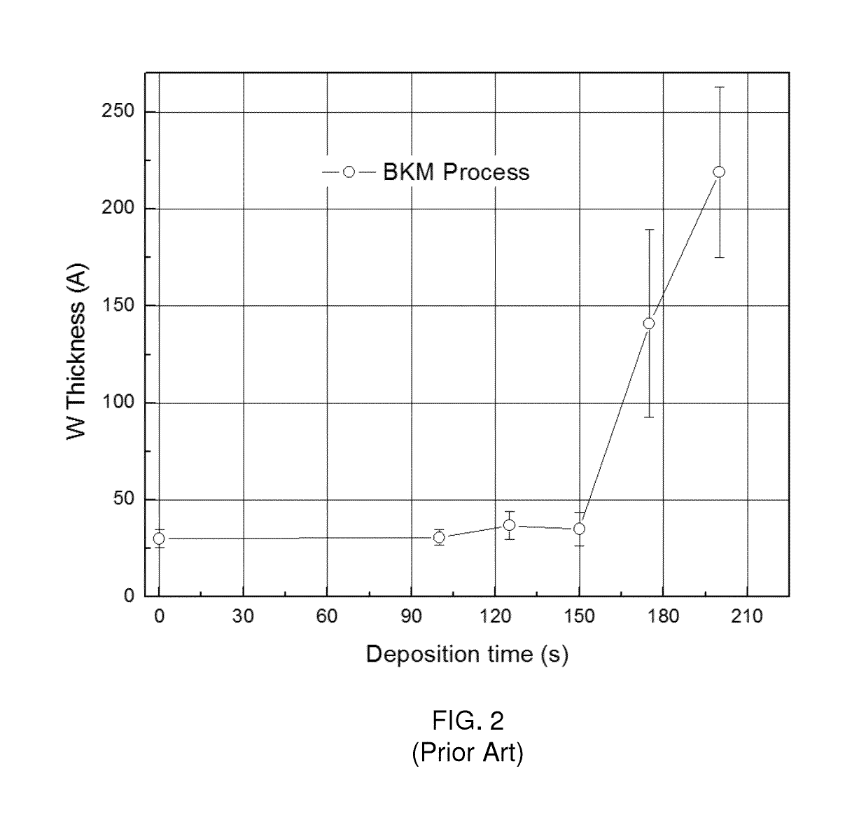

Nevertheless, the above current dep-etch-dep process has a built-in delay in the rate of metal growth during deposition, including the deposition of tungsten (W) metal for example. In particular, the delay in the growth of W deposition happens between the etching step and the second deposition step, which is explained below in more details with reference to FIG. 2.

FIG. 2 is a sample chart of experimental data illustrating delay in growth of metal deposition by the current dep-etch-dep process. More particularly, FIG. 2 illustrates the rate of tungsten deposition under the current dep-etch-dep process known as BKM process, wherein y-axis denotes thickness of tungsten deposited and x-axis denotes deposition time passed from the start of the second deposition step. From FIG. 2, it is clear that the thickness of tungsten deposited almost stayed the same, which is the thickness of tungsten mostly deposited during the first deposition step preceding the second deposition step, for the initial first at least 150 seconds after the second deposition step starts. The thickness of deposited tungsten then starts to increase, relatively linearly, after passing the initial first 150 seconds. This phenomenon of delayed deposition is similarly observed for other metal material as well when chemical vapor deposition (CVD) process or atomic layer deposition (ALD) process is used in the metal fill process.

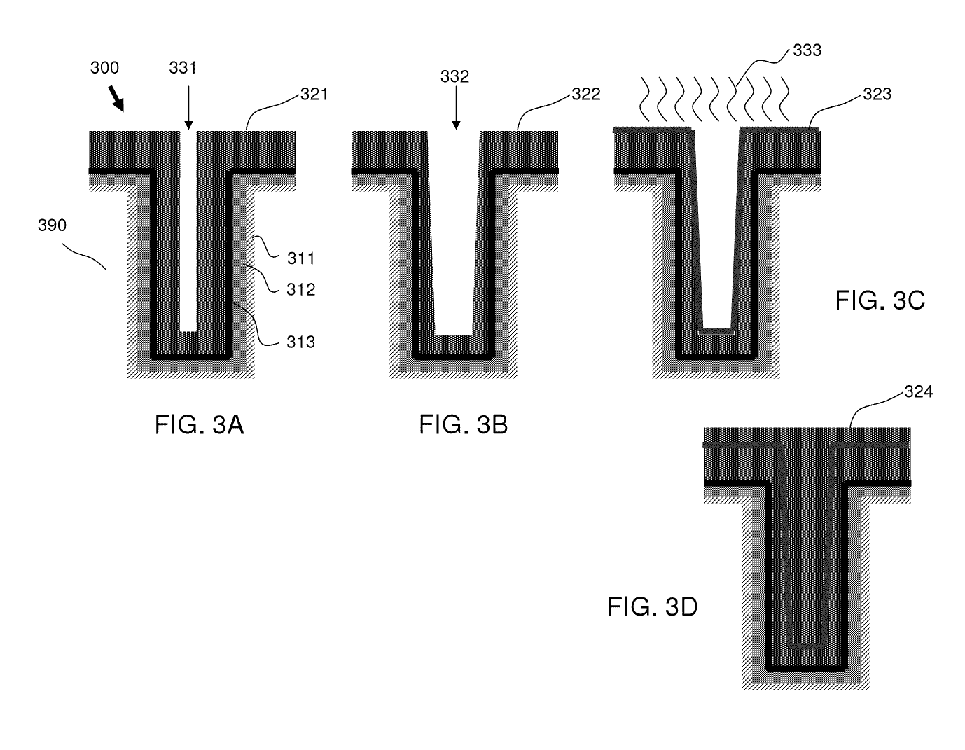

It is discovered by applicants that after the pinch-opening etching step in the current dep-etch-dep process, it may be the surface of the initially deposited tungsten (W) that does not possess a proper condition that allows additional W to build up immediately, at least for the initial certain period of time such as the first 150 seconds or so. It is further discovered by applicants that the delay in growth of W at the initial stage of the second deposition step may be due to accumulated nitride (N) content which, as a byproduct of gases used in the pinch-opening etching of the initially deposited tungsten layer, was caused to remain or stay at the surface after the etching and that prevented the happening of continuous tungsten growth immediately after etching because nitride surface generally does not provide favorable condition for tungsten growth and/or deposition. Based upon above discoveries, present invention provides an improved dep-etch-dep process, which is demonstratively illustrated in FIGS. 3A-3D, that mitigates the above problem.

More specifically, FIGS. 3A-3D are demonstrative illustrations of an improved dep-etch-dep process for performing metal fill according to one embodiment of present invention. In order to form a metal structure such as a metal gate, a metal contact, or a backend-of-the-line (BEOL) interconnect, to list some non-limiting examples, a structural opening 300 may first be created inside a semiconductor substrate 390 in a process of manufacturing semiconductor devices such as manufacturing a transistor with a replacement-metal-gate (RMG) or an interconnect structure generally associated with back-end-of-the-line. Subsequently, one or more layers of same or different material such as layer 311 and 312 (and possible other layers) may be deposited inside opening 300. For example, when forming a metal gate, a high-k dielectric layer 311 and a titanium-nitride (TiN) layer 312 may be deposited and when forming a metal interconnect or metal trench, an insulator layer 311 and a Ti/TiN metal diffusion barrier layer 312 may be deposited to line opening 300. Hereinafter, for the purpose of simplifying description without losing generality, forming a trench contact inside semiconductor substrate 390 is taken as an example for the explanation of embodiments of present invention wherein opening 300 may be described from time to time as a trench.

In order to fill trench 300, a seed layer 313 is then deposited on top of metal diffusion barrier layer 312 inside trench 300. Seed layer 313 helps and promotes subsequent metal deposition process. According to one embodiment of present invention, during a first deposition step of the improved dep-etch-dep process, a metal layer 321 may be deposited into trench 300 on top of seed layer 313. Trench 300 may be a high-aspect ratio trench, although the ratio of aspect of the trench, or via, or any other types of openings, may be higher or lower and may typically be around 1:5 to around 1:10. The first deposition step may leave a small opening 331 and the opening 331 may be particularly small in locations proximity to the top or upper portion of trench 300 due to a phenomenon commonly known as pinch caused during deposition of metal layer 321. After the initial or first deposition step, an anisotropic etching process, aided by etching dynamic of the trench profile, may be applied to remove some of the deposited metal, particularly around the top or upper portion of trench 300. This anisotropic etching process may involve remotely generated plasma under the environment of nitride containing gas of NF₃. This anisotropic etching process may transform the deposited metal layer 321 into an etching-modified metal layer 322 with a new opening 332 which is wide at the top and narrow at the bottom, as is demonstratively illustrated in FIG. 3B. The etching process may also remove some “roughness” of the deposited metal layer 331 resulting in a smoother surface of modified metal layer 322. Accordingly, resistance of the W deposited may be reduced.

According to one embodiment of present invention, the method may include applying a surface treatment step 333 after the anisotropic etching process to prepare the top surface of the etching-modified metal layer 322 for a follow-up second metal deposition step. More specifically, the surface treatment step 333 may include, according to one embodiment, subjecting etching-modified surface of metal layer 322 to an environment of mixed gases. The mixture of gases may be B₂H₆ mixed with WF₆ or silane mixed with WF₆. The treatment may be performed in a chamber following a chemical-vapor-deposition (CVD) process for about 10 seconds or less at a temperature of approximately 200 C˜400 C. Gases B₂H₆ and WF₆ or silane and WF₆ may be individually guided into and mixed inside the chamber where the treatment of the etching-modified metal surface is performed.

According to another embodiment, surface treatment step 333 may include subjecting etching-modified surface of metal layer 322 to alternate pulse gases of different types performed in an atomic-layer-deposition (ALD) process. For example, etching-modified surface of metal layer 322 may be subjected to or exposed to pulse gas of B₂H₆ (or silane) first and then to pulse gas of WF₆ and the above step may be repeated when necessary. Here, pulse gas means a short period of duration of gas. The necessity of repeating above step may be determined by observing improvement in a follow-up W deposition process in terms of the rate of W deposition. In one embodiment, subjecting the surface of metal layer 322 to the initial pulse gas of B₂H₆ (or silane) may be sufficient without any subsequent pulse gas of WF₆.

In some of the above surface treatment, since WF₆ is used which contains W element, some level of W deposition on top of the treated surface may be observed. The above surface treatment step 333 may be performed preferably at a temperature ranging between about 200 C and about 400 C for any appropriate time duration. Duration of the surface treatment is typically much shorter than the 150 seconds which is currently experienced by the nucleation delay in the current dep-etch-dep process. For example, in one embodiment the surface treatment may last only about 10 seconds and after those 10 seconds the second metal deposition step, of for example tungsten (W), may be started immediately. Nucleation or growth of tungsten may be observed without any noticeable delays as being compared with those that are often observed in the current dep-etch-dep process.

It is applicants' belief that surface treatment step 333, introduced by embodiment of present invention, applies Boron atoms supplied by the B₂H₆ gas (or other gas element) in passivating nitride (N) element that was caused to remain on the top surface of etching-modified metal layer 322 after the anisotropic etching, resulting in a passivated layer 323. The formation of passivation layer 323 effectively removes the root cause that is at least one of the contributing factors to the delay in the W deposition during the second deposition step. Following the surface treatment 333, additional metal of tungsten may be deposited into the treated opening 332, directly on top of passivation layer 323, which fills up the remaining opening nicely to form a final metal deposition 324.

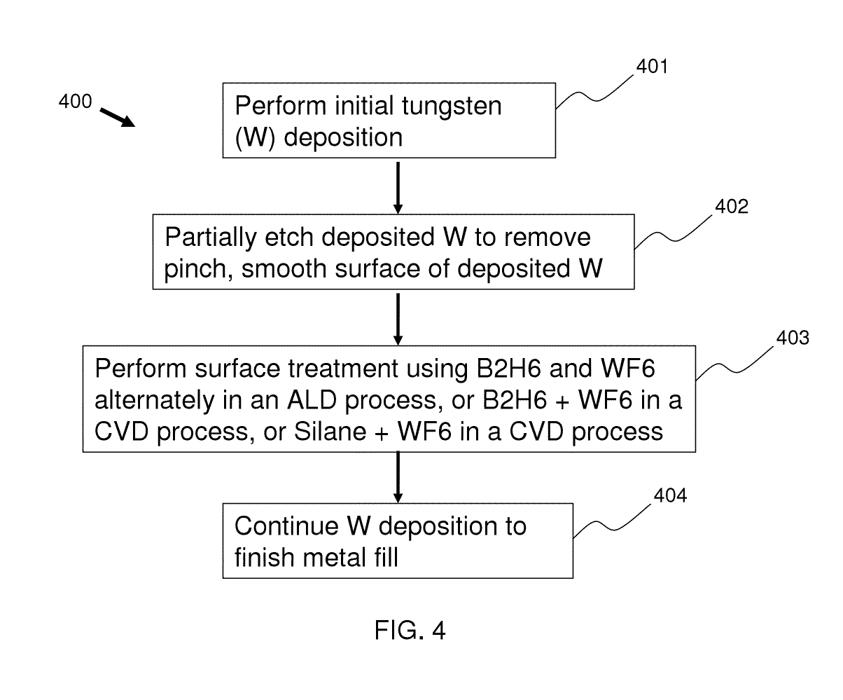

FIG. 4 is a simplified flow chart illustration of an improved dep-etch-dep process for performing metal fill according to another embodiment of present invention. More specifically, embodiment of present invention provides a method of performing metal fill in an opening of generally high-aspect ratio, although embodiment of present invention may be used in low-aspect ratio trenches and/or openings as well in removing any deposition and/or nucleation delay after surface etching that are not aspect ratio dependent. The method includes performing an initial or a first metal deposition step 401 such as depositing tungsten onto a surface of for example a trench. The method then includes partially etching the deposited metal 402 such as tungsten to remove any potential pinches, widen the opening particularly around the top or upper portion of the opening, and smooth the top surface; performing a surface treatment 403 to the etched surface using a special gas or gas mixture such as B₂H₆ or silane mixed with WF₆, or using alternate pulse gases of B₂H₆ and WF₆, that may passivate any accumulated nitride element on the top surface of the initially deposited and subsequently etching-modified tungsten layer; and then continuing performing a second W deposition step to finish the metal fill in the remaining opening.

It is to be noted that a surface treatment step, as described in above embodiments of present invention, may be applied effectively to deposition processes of other metals where delay of deposition may be observed and may be suspected as being caused by “foreign” chemicals on the surface where deposition is made. For example, in the deposition of tungsten, this “foreign” chemical may be nitride (N) which is then successfully passivated by applying a surface treatment involving the use of Boron containing gas.

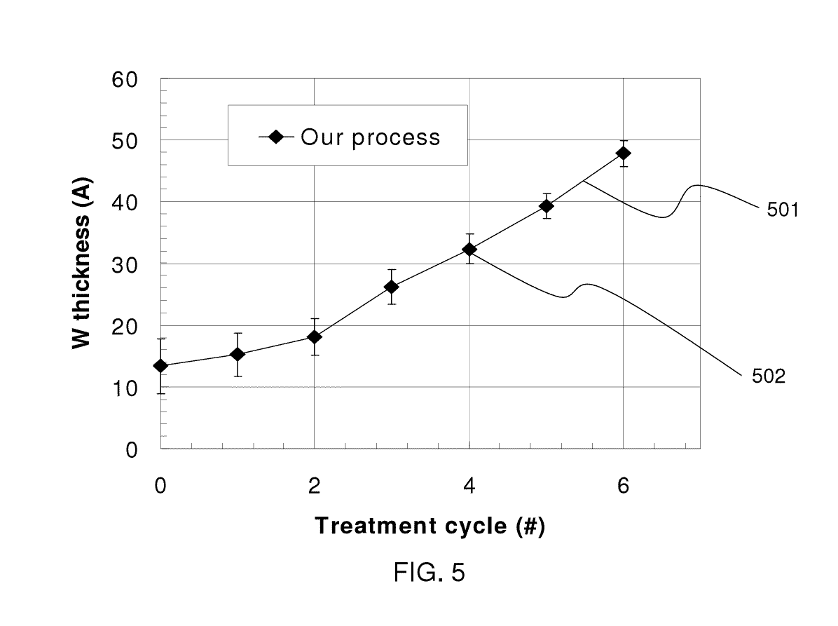

FIG. 5 is a sample data illustration demonstrating tungsten deposition during surface treatment according to one embodiment of present invention. In FIG. 5, y-axis denotes W thickness and x-axis denotes the number of surface treatment cycles being performed. In the experiment, alternate B₂H₆ and WF₆ pulse gases were used in an ALD process in treating deposited W surface and one cycle refers to one B₂H₆ pulse gas treatment followed by one WF₆ pulse gas treatment. FIG. 5 includes several experimental data 502 and the trend indicated by data 502, as being illustrated by a fitting curve 501 connecting data 502, shows that thickness of tungsten (W), including that deposited during the first W deposition step, continues to increase as being affected by the number of cycles of surface treatment.

More specifically, in FIG. 5, each cycle of surface treatment includes subjecting or exposing the etching-modified metal layer to B₂H₆ gas and then WF₆ gas alternately, in a form of pulse gases. The experimental data in FIG. 5 confirms that additional tungsten may be deposited during the surface treatment because of the use of W containing gas (such as WF₆). In other words, FIG. 5 demonstrates that the more number of cycles of surface treatment that the etching-modified surface of metal layer is subjected to, the more W is deposited during the treatment. Because W deposited during this surface treatment contains in general more impurity than those that are deposited or formed during the first and/or second “dedicated” W deposition steps, resistance of these deposited W generally tends to be higher, which in some instances may be slightly, than W that is deposited in their “dedicated” steps performed before or after the etching and surface treatment steps. In view of this, less number of cycles of surface treatment, such as if delay in nucleation at the second deposition step may be lessened or solved by using one single pulse of B₂H₆ gas so to avoid any W deposition, would be preferable from the stand point of reducing deposited metal resistance.

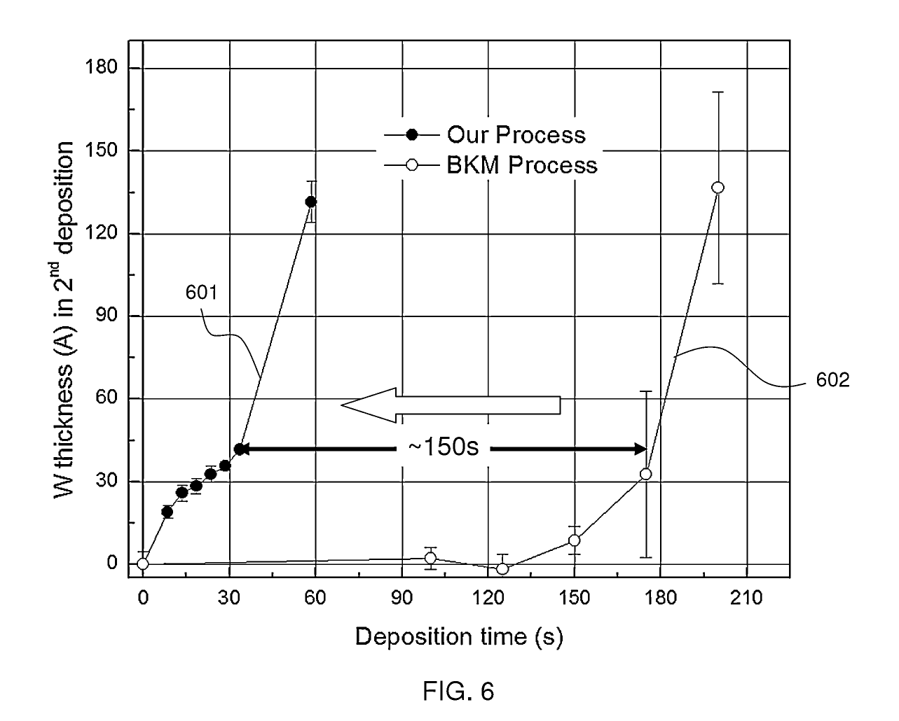

FIG. 6 is a sample data illustration demonstrating improvement in growth rate in an improved dep-etch-dep process according to another embodiment of present invention. More specifically, FIG. 6 illustrates an experimental comparison between applying the improved dep-etch-dep process, under one embodiment of present invention, and current dep-etch-dep process that does not have any surface treatment in between the two tungsten metal deposition steps. In FIG. 6, y-axis denotes tungsten thickness deposited during the second deposition step while x-axis denotes the effective deposition time measured in seconds from when the second deposition step starts. The x-axis is effective to include any additional time taken by the surface treatment made according to embodiment of present invention. When being compared with data 602 obtained under current BKM condition, the tungsten growth rate indicated by data 601 obtained in experiment adopting a process of applying surface treatment according to embodiment of present invention, shows a dramatic reduction, around 150 seconds, in the delay of nucleation growth that were experienced by a process, the current dep-etch-dep process, that does not adopt surface treatment.

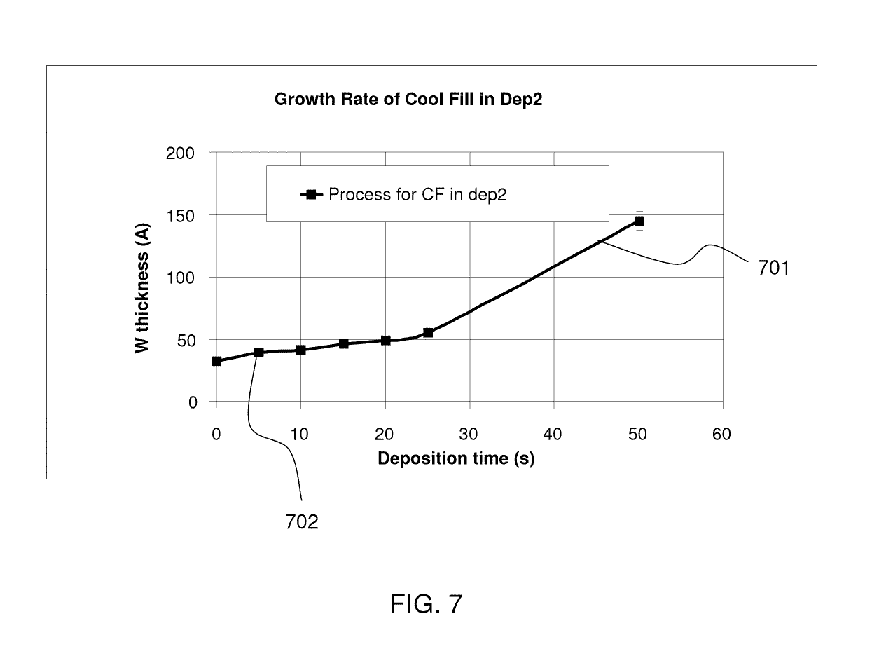

FIG. 7 is a sample data illustration demonstrating improvement in growth rate in an improved dep-etch-dep process according to yet another embodiment of present invention. More specifically, FIG. 7 illustrates tungsten growth rate during the second deposition process under cool fill condition at around 300 degree C., with y-axis denotes thickness of tungsten and x-axis denotes deposition time. Curve 701 represents the trend derived from experimental data 702, indicating that within 50 seconds deposited W may reach a thickness close to 150 A. In this specific experiment, two cycles of alternate pulse gases of B₂H₆ and WF₆ were used in performing surface treatment in between the first and the second W deposition steps.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the spirit of the invention.

What is claimed is:

1. A method comprising:
creating a structural opening in a process of manufacturing a semiconductor device;
depositing a first layer of metal inside said structural opening, said first layer of metal resulting in a narrowed opening, inside said structural opening, surrounded by said first layer of metal;
etching said first layer of metal to create an etching-modified surface of said first layer of metal;
passivating said etching-modified surface of said first layer of metal; and
depositing a second layer of metal inside said structural opening after said passivating, said second layer of metal substantially filling up said structural opening.

2. The method of claim 1, wherein both said first layer of metal and said second layer of metal are tungsten (W) metal.

3. The method of claim 2, wherein passivating said etching-modified surface of said first layer of metal comprises passivating nitride (N) element that are caused to remain at said etching-modified surface by etching said first layer of metal.

4. The method of claim 2, wherein passivating said etching-modified surface of said first layer of metal comprises exposing said etching-modified surface to a mixture of gases of B₂H₆ and WF₆ or a mixture of gases of silane and WF₆, for a duration of 10 seconds or less, in a chemical vapor deposition (CVD) process.

5. The method of claim 2, wherein passivating said etching-modified surface of said first layer of metal comprises exposing said etching-modified surface to alternate gases of B₂H₆ and WF₆ or alternate gases of silane and WF₆ in an atomic-layer-deposition (ALD) process.

6. The method of claim 1, wherein etching said first layer of metal comprises subjecting said first layer of metal to a plasma environment supported by a NF₃ gas to widen at least an upper portion of said narrowed opening formed by said first layer of metal.

7. The method of claim 1, wherein said semiconductor device is a transistor with a replacement-metal-gate (RMG) and wherein creating said structural opening comprises removing dummy material of a dummy gate where said RMG is to be formed thereby resulting in said structural opening.

8. The method of claim 1, wherein said semiconductor device is an interconnect structure and wherein creating said structural opening comprises creating a via hole in one or more dielectric layers inside said interconnect structure.

9. The method of claim 1, wherein passivating said etching-modified surface of said first layer of metal results in a passivation layer at said etching-modified surface, and wherein said second layer of metal is deposited directly on top of said passivation layer.

10. A method comprising:
creating an opening in a semiconductor structure;
depositing a first layer of metal inside said opening, said first layer of metal partially filling up said opening;
modifying a top surface of said first layer of metal in an etching process;
passivating said modified top surface of said first layer of metal to form a passivation layer; and
depositing a second layer of metal on top of said passivation layer.

11. The method of claim 10, wherein both said first layer of metal and said second layer of metal are tungsten (W) metal.

12. The method of claim 11, wherein modifying said top surface of said first layer of metal comprises subjecting said first layer of metal to a plasma environment supported by a NF₃ gas to widen an upper portion of said opening that is narrowed by said first layer of metal.

13. The method of claim 12, wherein passivating said modified top surface of said first layer of metal comprises passivating nitride (N) element that remain at said modified top surface of said first layer of metal after said etching process.

14. The method of claim 10, wherein passivating said modified top surface of said first layer of metal comprises exposing said modified top surface to a mixture of gases of B₂H₆ and WF₆, to a mixture of gases of silane and WF₆, to alternate gases of B₂H₆ and WF₆, or to alternate gases of silane and WF₆.

15. The method of claim 10, wherein said semiconductor structure is a transistor structure, and creating said opening comprises removing a dummy gate of said transistor structure in a replacement-metal-gate process to create said opening in an area of said dummy gate.

16. The method of claim 10, wherein said semiconductor structure is an interconnect structure and creating said opening comprises creating a via hole or a trench in one or more dielectric layers of said interconnect structure.

17. A method comprising:
creating an opening inside a semiconductor structure;
depositing a first layer of metal inside said opening, said first layer of metal partially filling up said opening;
etching said first layer of metal to have a modified top surface of said first layer of metal;
passivating said modified top surface of said first layer of metal;
depositing a second layer of metal inside said opening after said modified top surface of said first layer of metal is passivated, said second layer of metal partially filling up said opening;
etching said second layer of metal to have a modified top surface of said second layer of metal;
passivating said modified top surface of said second layer of metal; and
depositing a third layer of metal inside said opening after said modified top surface of said second layer of metal is passivated, said third layer of metal substantially filling up said opening.

18. The method of claim 17, wherein both said first, said second, and said third layer of metal are tungsten (W) metal.

19. The method of claim 17, wherein modifying said top surface of said first and said second layer of metal comprises subjecting said first and said second layer of metal to a plasma environment, respectively, supported by a NF₃ gas to widen an upper portion of said opening narrowed by said first and said second layer of metal, respectively.

20. The method of claim 17, wherein passivating said modified top surface of said first and said second layer of metal comprises passivating nitride (N) element that remain at said modified top surfaces after said etching thereof respectively.
